(19) United States
(12) Patent Application Publication
(10) Pub. No.: US 2022/0149789 A1
(43) Pub. Date: May 12, 2022

(54) GAIN AND PHASE STABILIZED AMPLIFIER

(71) Applicant: Analog Devices International Unlimited Company, Limerick (IE)

(72) Inventors: Ed BALBONI, Littleton, MA (US); Ovidiu Vasile BALAJ, Kirkland (CA)

(73) Assignee: Analog Devices International Unlimited Company, Limerick (IE)

(21) Appl. No.: 17/580,302

(22) Filed: Jan. 20, 2022

Related U.S. Application Data
(60) Provisional application No. 63/144,754, filed on Feb. 2, 2021.

(51) Int. Cl. H03F 1/30; H03F 1/02; H03F 3/21; H03F 3/193

(52) U.S. Cl. CPC H03F 1/30; H03F 3/193; H03F 3/21; H03F 1/0222

(57) ABSTRACT

One embodiment is a lower power technique to compensate for radio frequency (RF) amplifier gain and phase over temperature and part-to-part variation for particular use in phased array (PA) applications.

### CROSS-REFERENCE TO RELATED APPLICATION

This patent application claims the benefit of the filing date of U.S. Provisional Patent Application Ser. No. 63/144,754, filed on Feb. 2, 2021, and entitled “GAIN AND PHASE STABILIZED AMPLIFIER,” the content of which is hereby expressly incorporated by reference in its entirety.

### FIELD OF THE DISCLOSURE

This disclosure relates generally to the field of electronics and, more particularly, to a gain and phase stabilized amplifier circuit.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which

FIG. 1 is a schematic block diagram of a circuit for providing gain and phase compensation for a phase array (PA) path according to some embodiments of the present disclosure; and

FIG. 2 is a schematic block diagram of a circuit for providing gain and phase compensation for a phase array (PA) path according to alternative embodiments of the present disclosure.

### DETAILED DESCRIPTION

The systems, methods, and devices of this disclosure each have several innovative aspects, no single one of which is solely responsible for all desirable attributes disclosed herein. Details of one or more implementations of the subject matter described in this specification are set forth in the description below and the accompanying drawings.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. When used herein, the notation “A/B/C” means (A), (B), and/or (C). Although certain elements may be referred to in the singular herein, such elements may include multiple sub-elements. For example, “an electrically conductive material” may include one or more electrically conductive materials. In another example, “a dielectric material” may include one or more dielectric materials.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

In the drawings, a particular number and arrangement of structures and components are presented for illustrative purposes and any desired number or arrangement of such structures and components may be present in various embodiments. Further, the structures shown in the figures may take any suitable form or shape according to material properties, fabrication processes, and operating conditions. For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 110a-110e), such a collection may be referred to herein without the letters (e.g., as “110”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Phased arrays (PAs) need to maintain tight control on the relative amplitude and phase of the transmit PA path to point a narrow beam in a known direction. This control needs to be maintained over a temperature range. Power efficiency is also important, since the number of PA transmit paths can be large. For example, in spaceborne applications, 5,000-50,000 transmit paths are typical.

Transmit PAs in spaceborne arrays have large gains, e.g., on the order of 60 dB, and the variation in gain and phase from unit-to-unit and over a range of temperatures may create a beam error that needs to be compensated for. Area and power consumption are also critical in PA applications.

Embodiments described herein include a technique to compensate RF amplifier gain and phase over temperature and for part-to-part variation. The technique is a low power technique, which is critical for PA applications.

In PAs, the RF amplifier needs to have control of the gain and phase from unit to unit and over operating temperature. Most techniques for providing these features consume too much power when applied to PAs, where there are many signal chains and the relative gain and phase errors lead to PA beam pattern errors.

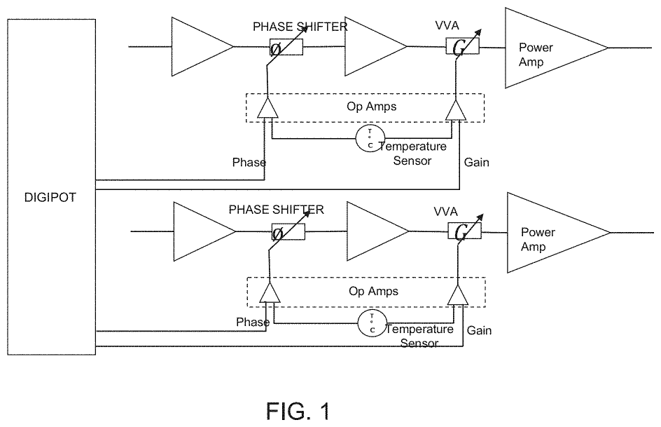

In accordance with features of an embodiment described herein, as shown in FIG. 1, a passive phase adjustment circuit, a phase shifter and passive amplitude adjustment circuit, and a VVA are added into the RF signal path. The phase and gain can be adjusted using control voltages applied to each function. Part-to-part variation is compensated by measuring these parameters in the factory and then applying a calibration voltage using a DAC connected to a non-volatile memory. Temperature is compensated for using a temperature sensor with the proper gain for phase adjustment and gain adjustment set by characterizing the amplifier and using op amps with the correct resistor values to both sum in the temperature compensation voltage with the factory calibration voltage and set the correct scale factors. This approach assumes amplifier gain and phase variation with temperate is relatively the same for a given RF amplifier chain. This technique may be implemented at very low added power dissipation.

IAs illustrated in FIG. 1, a digital potentiometer (or “digiPOT”), which includes a nonvolatile memory (NVM), may be used to factory trim the gain and phase of each transmit PA path using an in-line voltage variable attenuator (VVA) and a phase shifter. This approach is very low power consumption. Alternatively, the gain control can use the PA amplifier's gate control to adjust gain.

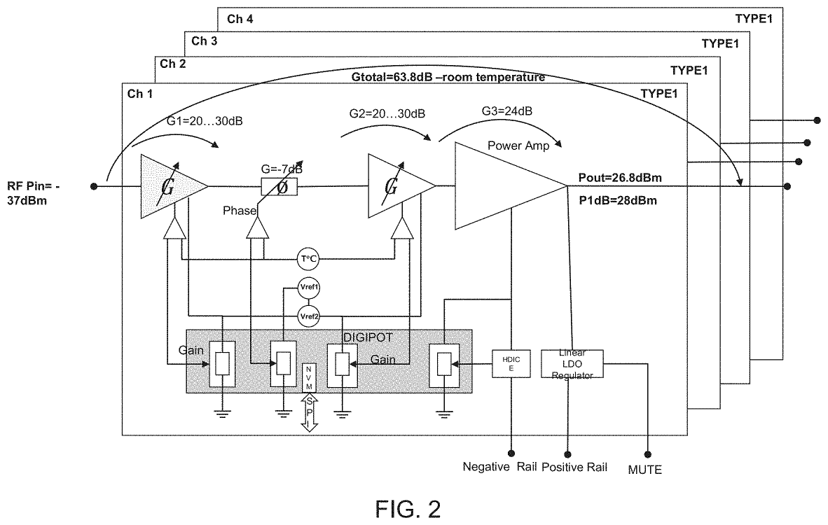

As illustrated in FIG. 2, phase and amplitude variation with temperature may additionally be compensated for “open loop” by using a temperature sensor and characterizing the gain(temp) and phase(temp) of the signal chain and then adding in the compensating trims to gain and phase. Gain and phase vs temperature is typically highly repeatable unit to unit, so characterization is suitable.

As previously noted, minimizing power consumption is critical, and the embodiments described herein add very little additional power to the transmit path.

It should be noted that all of the specifications, dimensions, and relationships outlined herein (e.g., the number of elements, operations, steps, etc.) have only been offered for purposes of example and teaching only. Such information may be varied considerably without departing from the spirit of the present disclosure, or the scope of the appended claims. The specifications apply only to one non-limiting example and, accordingly, they should be construed as such. In the foregoing description, exemplary embodiments have been described with reference to particular component arrangements. Various modifications and changes may be made to such embodiments without departing from the scope of the appended claims. The description and drawings are, accordingly, to be regarded in an illustrative rather than in a restrictive sense.

Note that with the numerous examples provided herein, interaction may be described in terms of two, three, four, or more electrical components. However, this has been done for purposes of clarity and example only. It should be appreciated that the system may be consolidated in any suitable manner. Along similar design alternatives, any of the illustrated components, modules, and elements of the FIGURES may be combined in various possible configurations, all of which are clearly within the broad scope of this Specification. In certain cases, it may be easier to describe one or more of the functionalities of a given set of flows by only referencing a limited number of electrical elements. It should be appreciated that the electrical circuits of the FIGURES and its teachings are readily scalable and may accommodate a large number of components, as well as more complicated/sophisticated arrangements and configurations. Accordingly, the examples provided should not limit the scope or inhibit the broad teachings of the electrical circuits as potentially applied to myriad other architectures.

It should also be noted that in this Specification, references to various features (e.g., elements, structures, modules, components, steps, operations, characteristics, etc.) included in “one embodiment”, “exemplary embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments.

It should also be noted that the functions related to circuit architectures illustrate only some of the possible circuit architecture functions that may be executed by, or within, systems illustrated in the FIGURES. Some of these operations may be deleted or removed where appropriate, or these operations may be modified or changed considerably without departing from the scope of the present disclosure. In addition, the timing of these operations may be altered considerably. The preceding operational flows have been offered for purposes of example and discussion. Substantial flexibility is provided by embodiments described herein in that any suitable arrangements, chronologies, configurations, and timing mechanisms may be provided without departing from the teachings of the present disclosure.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

Note that all optional features of the device and system described above may also be implemented with respect to the method or process described herein and specifics in the examples may be used anywhere in one or more embodiments.

The “means for” in these instances (above) may include (but is not limited to) using any suitable component discussed herein, along with any suitable software, circuitry, hub, computer code, logic, algorithms, hardware, controller, interface, link, bus, communication pathway, etc.

Note that with the example provided above, as well as numerous other examples provided herein, interaction may be described in terms of two, three, or four network elements. However, this has been done for purposes of clarity and example only. In certain cases, it may be easier to describe one or more of the functionalities of a given set of flows by only referencing a limited number of network elements. It should be appreciated that topologies illustrated in and described with reference to the accompanying FIGURES (and their teachings) are readily scalable and may accommodate a large number of components, as well as more complicated/sophisticated arrangements and configurations. Accordingly, the examples provided should not limit the scope or inhibit the broad teachings of the illustrated topologies as potentially applied to myriad other architectures.

It is also important to note that the steps in the preceding flow diagrams illustrate only some of the possible signaling scenarios and patterns that may be executed by, or within, communication systems shown in the FIGURES. Some of these steps may be deleted or removed where appropriate, or these steps may be modified or changed considerably without departing from the scope of the present disclosure. In addition, a number of these operations have been described as being executed concurrently with, or in parallel to, one or more additional operations. However, the timing of these operations may be altered considerably. The preceding operational flows have been offered for purposes of example and discussion. Substantial flexibility is provided by communication systems shown in the FIGURES in that any suitable arrangements, chronologies, configurations, and timing mechanisms may be provided without departing from the teachings of the present disclosure.

Although the present disclosure has been described in detail with reference to particular arrangements and configurations, these example configurations and arrangements may be changed significantly without departing from the scope of the present disclosure. For example, although the present disclosure has been described with reference to particular communication exchanges, embodiments described herein may be applicable to other architectures.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 142 as it exists on the date of the filing hereof unless the words “means for” or “step for” are specifically used in the particular claims; and (b) does not intend, by any statement in the specification, to limit this disclosure in any way that is not otherwise reflected in the appended claims.

What is claimed is:

1. An apparatus for performing gain and phase calibration and compensation for a phased array (PA) path, the apparatus comprising:
a digital potentiometer for outputting a phase compensation signal to a phase shifter and a gain compensation signal to a variable voltage attenuator (VVA); and
a temperature sensor for outputting a temperature compensation signal to the phase shifter and the VVA;
wherein the phase shifter and the VVA perform gain and phase calibration in accordance with the compensation signals received from the digital potentiometer and the temperature sensor.
